(19) United States
(12) Patent Application Publication
(10) Pub. No.: US 2007/0290279 A1
(43) Pub. Date: Dec. 20, 2007

(54) Semiconductor device including groove pattern around effective chip and method for fabricating the same

(76) Inventor: Kentaro Imamizu, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/802,528

(22) Filed: May 23, 2007

(30) Foreign Application Priority Data
May 23, 2006 (JP) 2006-143120

(51) Int. Cl. H01L 29/92; H01L 21/336

(52) U.S. Cl. 257/411; 438/287; 257/E29.342; 257/E21.409

(57) ABSTRACT

A semiconductor device includes an interlayer insulating film, a first interconnect material, and a second interconnect material. The interlayer insulating film is formed on a semiconductor substrate including an effective chip. The first interconnect material is formed in an interconnect pattern in the interlayer insulating film. The interconnect pattern is made in a region above the effective chip. The second interconnect material is formed in a groove pattern in the interlayer insulating film. The groove pattern is made between the region above the effective chip and a region above an edge of the semiconductor substrate. The second interconnect material separates the interlayer insulating film into an inner circumferential portion which includes the region above the effective chip and an outer circumferential portion which does not include the region above the effective chip.

### CROSS-REFERENCE TO RELATED APPLICATIONS

This application is based upon and claims the benefit of priority from prior Japanese Patent Application No. 2006-143120, filed May 23, 2006, the entire contents of which are incorporated herein by reference.

### BACKGROUND OF THE INVENTION

1. Field of the Invention

The present invention relates to a semiconductor device and a method for fabricating the same, and for example, to a semiconductor device in which peel-off of a low-dielectric-constant insulating film (low-k film) is suppressed and a method for fabricating the same.

2. Description of the Related Art

In order to decrease an inter-interconnect parasitic capacitance of a highly integrated semiconductor device, a low-k film having a specific dielectric constant lower than that of a silicon oxide film is being introduced as a material for an interlayer insulating film.

However, generally the low-k film has weaker mechanical strength and bonding strength of a film boundary compared with the silicon oxide film. For this reason, the peel-off is easily produced when a load is applied onto a semiconductor wafer in the chemical mechanical polishing (CMP) process, for example. Furthermore, because generally a high load tends to be applied on an outer circumference of the wafer (substrate) in the CMP process, the peel-off is easily produced from an edge of the wafer (substrate).

For example, Jpn. Pat. Appln. KOKAI Publication No. 2005-183779 proposes protection of the interlayer insulating film. In a configuration disclosed in Jpn. Pat. Appln. KOKAI Publication No. 2005-183779, a dummy pattern which partitions a low-k film into plural isolated regions is formed in an interlayer insulating film which does not include an interconnect pattern on a semiconductor substrate in order to suppress erosion or dishing caused by interconnection density. A shear stress to the low-k film is released by partitioning the low-k film into the plural isolated regions, when the CMP process is performed to form buried interconnects. Even if the low-k film is peeled off or cracks, propagation of the peel-off or crack to an element region is suppressed.

### BRIEF SUMMARY OF THE INVENTION

A semiconductor device according to an aspect of the present invention includes:

an interlayer insulating film formed on a semiconductor substrate including an effective chip;

a first interconnect material formed in an interconnect pattern in the interlayer insulating film, the interconnect pattern being made in a region above the effective chip; and

a second interconnect material formed in a groove pattern in the interlayer insulating film, the groove pattern being made between the region above the effective chip and a region above an edge of the semiconductor substrate, the second interconnect material separating the interlayer insulating film into an inner circumferential portion which includes the region above the effective chip and an outer circumferential portion which does not include the region above the effective chip.

A method for fabricating a semiconductor device according to an aspect of the present invention includes:

forming an interlayer insulating film on a semiconductor substrate including an effective chip;

making an interconnect pattern in a region above the effective chip in the interlayer insulating film;

making a groove pattern between the region above the effective chip and a region above an edge of the semiconductor substrate in the interlayer insulating film, the groove pattern separating the interlayer insulating film into an inner circumferential portion which includes the region above the effective chip and an outer circumferential portion which does not include the region above the effective chip; and

forming interconnect materials in the groove pattern and the interconnect pattern.

### BRIEF DESCRIPTION OF THE SEVERAL VIEWS OF THE DRAWING

FIG. 1 is a plan view showing an exemplary semiconductor device according to an embodiment of the invention;

FIG. 2 is a sectional view taken along a line 2-2 of FIG. 1;

FIG. 3 a plan view showing a semiconductor device according to a modification of the embodiment of the invention;

FIG. 4 is a sectional view specifically showing the semiconductor device according to the embodiment of the invention;

FIGS. 5 to 15 are sectional views sequentially showing first to eleventh processes of fabricating the semiconductor device according to the embodiment of the invention;

FIG. 16 is a plan view showing the semiconductor device according to the embodiment of the invention, and showing an example of formation of a groove pattern;

FIG. 17 is a schematic view showing an exposure apparatus which is used to form a groove pattern in the semiconductor device according to the embodiment of the invention;

FIG. 18 is a plan view showing a semiconductor device according to a modification of the embodiment of the invention and showing another example of the formation of a groove pattern; and

FIG. 19 is an enlarged view showing a region A of FIG. 18.

### DETAILED DESCRIPTION OF THE INVENTION

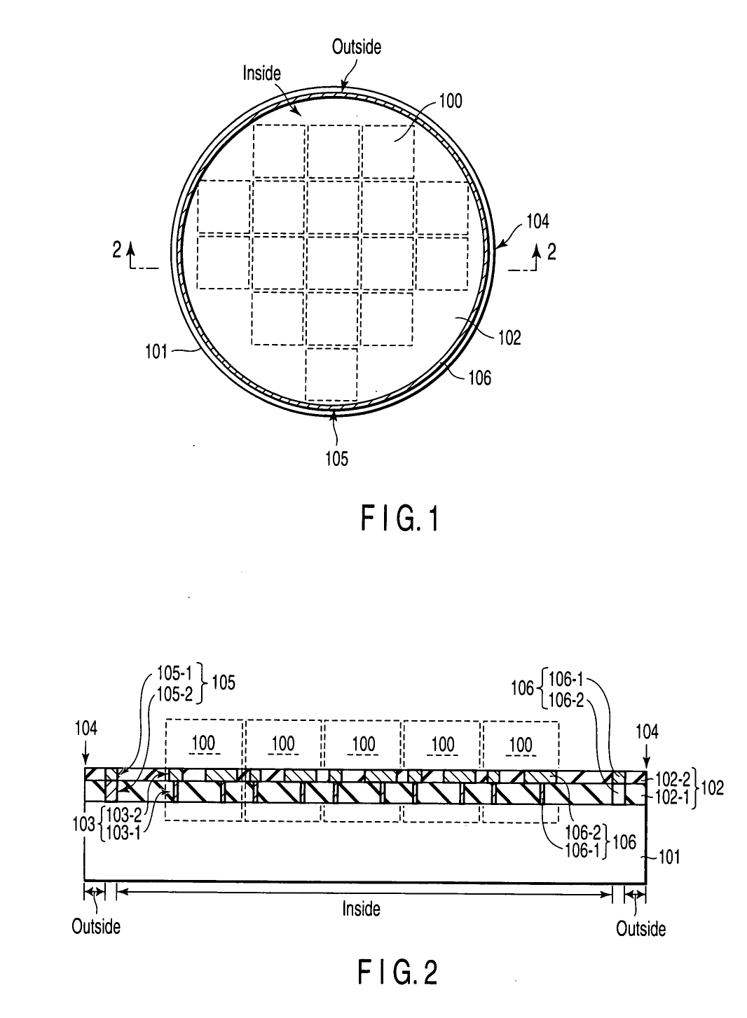

A semiconductor device according to an embodiment of the invention and a method for fabricating the same will be described below. FIG. 1 is a plan view showing a semiconductor device according to the embodiment of the invention, and FIG. 2 is a sectional view taken along a line 2-2 of FIG. 1.

As shown in FIGS. 1 and 2, the semiconductor device of the embodiment has a semiconductor substrate 101 including effective chips 100. As used herein, the effective chip 100 shall mean a region in which a semiconductor element is formed and which should be separated into semiconductor chips by a dicing process. In the semiconductor substrate 101, regions except for the effective chips 100 are not used for a product and disposed after the dicing process. One example of the semiconductor substrate 101 is a semiconductor wafer. An interlayer insulating film 102 is formed on the semiconductor substrate 101. An example of the interlayer insulating film 102 is an insulating film including a low-k film. In the specification, the low-k film is defined as an insulating film whose specific dielectric constant is lower than 3.0 or an insulating film having a specific dielectric constant lower than that of a silicon oxide film. Examples of the insulating film include a film obtained by containing any one of C, H, N, F, Ge, B, P, As, Mn, BF₂, Zn, Sn, Sb, and Hf in a silicon oxide film, and an organic polymer film.

In the interlayer insulating film 102, an interconnect pattern 103 is made in a region on the effective chip 100 (the interconnect pattern is omitted in FIG. 1).

In the interlayer insulating film 100, a groove pattern 105 is made between the effective chip 100 and an edge 104 of the semiconductor substrate 101.

The groove pattern 105 separates the interlayer insulating film 102 into an inner circumferential portion (inside) which includes the effective chip 100 and an outer circumferential portion (outside) which does not includes the effective chip 100. The groove pattern 105 of the embodiment is made in a circular shape along the edge 104 of the semiconductor substrate 101. Interconnect materials (conductive materials) 106 are formed in the groove pattern 105 and the interconnect pattern 103.

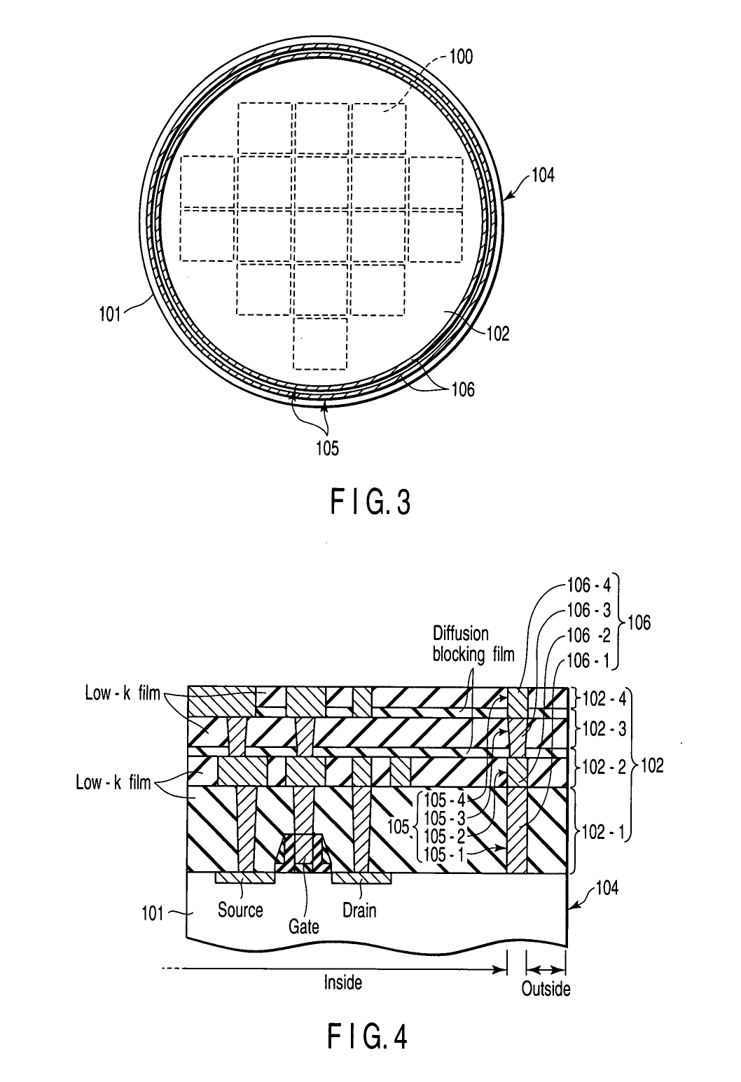

Although the one groove pattern 105 is made in the embodiment, the plural groove patterns 105 may be made. In the case of the plural groove patterns 105, they may be made as shown in FIG. 3, for example. FIG. 3 is a plan view showing a semiconductor device according to a modification of the embodiment. As shown in FIG. 3, the plural groove patterns 105 may concentrically be made.

In the semiconductor device of the embodiment, the circular groove pattern 105 is made along the edge 104 of the semiconductor substrate 101 in the interlayer insulating film 102. The groove pattern 105 separates the interlayer insulating film 102 into the inner circumferential portion (inside) which includes the effective chip 100 and the outer circumferential portion (outside) which does not include the effective chip 100. Therefore, even if the interlayer insulating film 102 is peeled off from the edge 104 in a CMP process or the like, the film peeling is stopped at the groove pattern 105. This suppresses the influence of the film peeling on the inner circumferential portion (inside) including the effective chip 100.

Accordingly, it is possible to provide a semiconductor device having a structure in which, even if the film is peeled off from the edge 104 of the semiconductor substrate 101, the progress of the film peeling can be stopped, and a method for fabricating the same.

In the embodiment, the interconnect material 106 is formed in the groove pattern 105. Forming the interconnect material 106 in the groove pattern 105 enables enhancement of the mechanical strength of the outer circumferential portion (outside) of the interlayer insulating film 102 separated by the groove pattern 105. Generally, in the outer circumferential portion (outside) of the interlayer insulating film 102, the mechanical strength is excessively small because a contact area with the underlying layer is decreased to easily make the film peel. This is disadvantageous in the process adopting the CMP method.

In the embodiment, on the other hand, the interconnect material 106 is formed in the groove pattern 105. For this reason, the interconnect material 106 adheres tightly to the outer circumferential portion (outside) of the interlayer insulating film 102, which allows the mechanical strength to be enhanced in the outer circumferential portion (outside).

The interconnect material 106 formed in the groove pattern 105 adheres tightly to not only the outer circumferential portion (outside) of the interlayer insulating film 102 but also the inner circumferential portion (inside) of the interlayer insulating film 102, which allows the mechanical strength to be also enhanced in the inner circumferential portion (inside).

Accordingly, in the embodiment, the outer circumferential portion (outside) and inner circumferential portion (inside) of the interlayer insulating film 102 hardly peel off compared with a case where the interconnect material 106 is absent in the groove pattern 105. This is advantageous in the process adopting the CMP method.

The specific structure of the semiconductor device of the embodiment will be described below with reference to FIG. 2. FIG. 2 is the sectional view showing the semiconductor device of the embodiment.

As shown in FIG. 2, the interlayer insulating film 102 has a multi-layer structure. By way of example, FIG. 2 shows a case where the interlayer insulating film 102 includes a first interlayer insulating film 102-1 and a second interlayer insulating film 102-2. The first interlayer insulating film 102-1 is formed on the semiconductor substrate 101, while the second interlayer insulating film 102-2 is formed on the first interlayer insulating film 102-1. In this case, the interconnect pattern 103 includes a first interconnect pattern 103-1 formed in the first interlayer insulating film 102-1 and a second interconnect pattern 103-2 formed in the second interlayer insulating film 102-2. Similarly, the groove pattern 105 includes a first groove pattern 105-1 made in the first interlayer insulating film 102-1 and a second groove pattern 105-2 made in the second interlayer insulating film 102-2. Similarly, the interconnect material 106 includes a first interconnect material 106-1 and a second interconnect material 106-2. The first interconnect materials 106-1 are formed in the first interconnect pattern 103-1 and the first groove pattern 105-1. The second interconnect materials 106-2 are formed in the second interconnect pattern 103-2 and the second groove pattern 105-2. The second interconnect material 106-2 is electrically connected to the first interconnect material 106-1.

The first interconnect pattern 103-1 shown in FIG. 2 is a hole pattern which is utilized as a pattern of a contact or a via hole. The contact reaches the semiconductor substrate 101 or a diffusion layer formed in the semiconductor substrate 101. The via hole connects an interconnect on an upper layer and an interconnect on a lower layer. For example, when the semiconductor substrate 101 is made of silicon, tungsten is used as the interconnect material for the contact. For example, copper is used as the interconnect material for the via hole.

The second interconnect pattern 103-2 shown in FIG. 2 is a line pattern. The line pattern is utilized as patterns of, for example, interconnects which connect electrodes of transistors, interconnects which connect interconnects, and interconnects which supply electric power to transistors. An example of the interconnect material for such interconnects is copper.

In FIG. 2, the interlayer insulating film 102 has the two layers of the interlayer insulating films 102-1 and 102-2. However, the number of layers in the interlayer insulating film 102 can be arbitrarily selected. FIG. 4 shows another example of the interlayer insulating film 102. FIG. 4 is a sectional view showing another example of the semiconductor device. The interlayer insulating film 102 of FIG. 4 has four layers (102-1 to 102-4). The number of interlayer insulating film 102 layers is appropriately selected according to the number of interconnect layers.

Although it is not always limited to the case in which the interlayer insulating films 102 are laminated, preferably the groove pattern 105 (105-1 to 105-4) is made from the surface of the semiconductor substrate 101 to the upper surface of the interlayer insulating film 102 (102-1 to 102-4) (see FIGS. 2 and 4), and the interconnect material 106 (106-1 to 106-4) is formed in a fence shape from the surface of the semiconductor substrate 101 to the upper surface of the interlayer insulating film 102 (102-1 to 102-4).

The above configuration has the following advantages.

It is assumed that the groove pattern 105 or 105-1 to 105-4 is interrupted in the middle of the interlayer insulating film 102 or in the middle of the laminated interlayer insulating films 102-1 to 102-4. That is, the outer circumferential portion (outside) and the inner circumferential portion (inside) of the interlayer insulating film 102 (102-1 to 102-4) are connected to each other in the region where the groove pattern 105 (105-1 to 105-4) is interrupted. When the interlayer insulating film 102 is peeled off from the edge 104 in this state, the film peeling possibly propagates from the outer circumferential portion (outside) to the inner circumferential portion (inside) through the portion where the outer circumferential portion (outside) and the inner circumferential portion (inside) are connected to each other. Therefore, the effect of improving the yield of the semiconductor device is reduced. In order to prevent the effect of improving the yield of the semiconductor device from being reduced, the groove pattern 105 (105-1 to 105-4) is made from the surface of the semiconductor substrate 101 to the upper surface of the interlayer insulating film 102 (102-1 to 102-4) (see FIGS. 2 and 4), and the interconnect material 106 (106-1 to 106-4) is formed in a fence shape from the surface of the semiconductor substrate 101 to the upper surface of the interlayer insulating film 102 (102-1 to 102-4).

For example, an insulating film including a low-k film is used as the interlayer insulating film 102 (102-1 to 102-4). Examples of the structure of the insulating film including the low-k film include a single-layer structure made of a low-k film, a laminated structure made of a silicon oxide film and a low-k film, a laminated structure made of a diffusion blocking film and a low-k film, and a laminated structure made of a diffusion blocking film, a silicon oxide film, and a low-k film. In FIG. 4, for example, the first-layer interlayer insulating film 102-1 is formed by the single-layer structure made of a low-k film, the second-layer interlayer insulating film 102-2 and the third-layer interlayer insulating film 102-3 are formed by the laminated structure made of a diffusion blocking film and a low-k film, and the fourth-layer interlayer insulating film 102-4 is formed by the single-layer structure made of a low-k film.

In the above structure of the interlayer insulating film, the low-k film itself may be formed by a laminated structure in which different low-k films are laminated.

Although the insulating film including the low-k film is used as the interlayer insulating film 102 (102-1 to 102-4) in the embodiment, the embodiment is not limited thereto. For example, a single-layer structure made of a silicon oxide film or a laminated structure made of a silicon oxide film and a diffusion blocking film may be used as the interlayer insulating film 102 (102-1 to 102-4). Because the silicon oxide film has the better adhesion property to the underlying layer when compared with the low-k film, the silicon oxide film is hardly peeled off, but not nothing. In the embodiment, the interlayer insulating film 102 (102-1 to 102-4) has the single-layer structure made of the silicon oxide film and the laminated structure made of the silicon oxide film and the diffusion blocking film. Therefore, the groove pattern 105 (105-1 to 105-4) is made in the interlayer insulating film 102 (102-1 to 102-4), and the interconnect material 106 (106-1 to 106-4) is formed in the groove pattern 105 (105-1 to 105-4). This enables a probability of occurrence of film peeling to be lowered even if the insulating film including the low-k film is not used as the interlayer insulating film 102 (102-1 to 102-4).

A method for fabricating the semiconductor device of the embodiment will be described below.

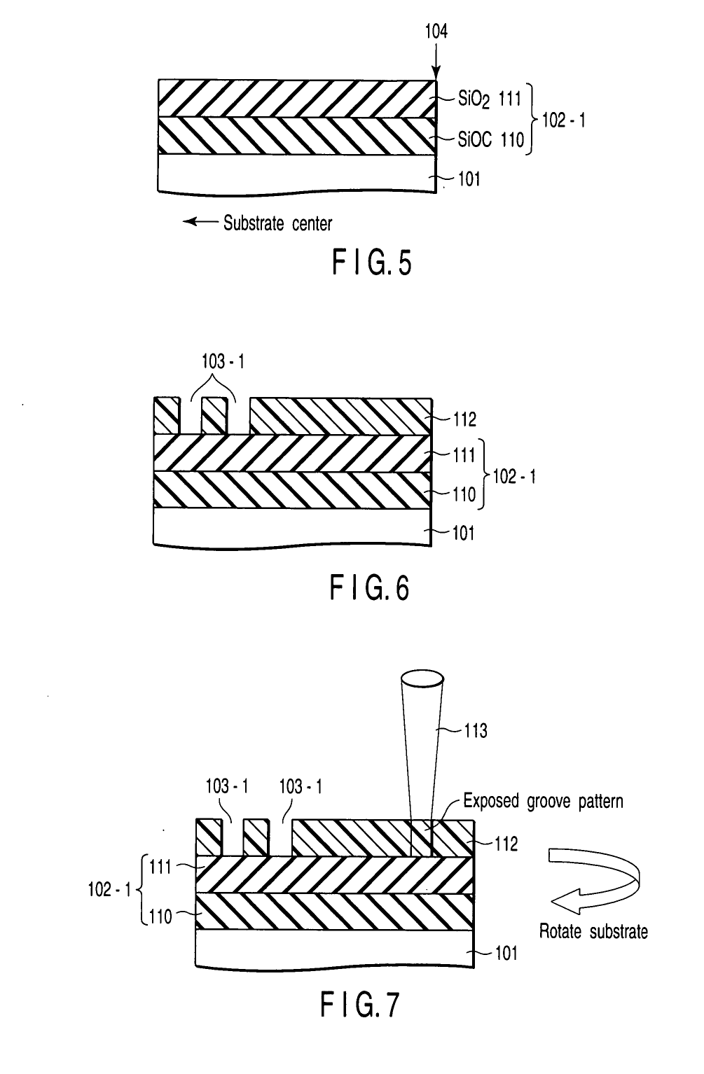

FIGS. 5 to 15 are sectional views sequentially showing processes for fabricating the semiconductor device according to the embodiment of the invention.

As shown in FIG. 5, a low-k film (for example, SiOC) 110 having a thickness of about 100 nm is formed on the semiconductor substrate (for example, semiconductor wafer) 101, and an insulating film (for example, SiO₂) 111 having a thickness of about 100 nm is formed on the low-k film 110. The low-k film 110 is a film obtained by containing at least one of elements of C, H, F, Ge, B, P, As, Mn, BF₂, Zn, Sn, Sb, and Hf in the silicon oxide film. The low-k film 110 can be formed by plasma CVD, reactive spattering using a Si target and an oxygen (O) system gas or a nitrogen (N) system gas, vacuum evaporation, coating, and the like. The low-k film 110 and the insulating film 111 can also be laminated not only in two layers but also in three layers or more. Alternatively, the single-layer structure may be formed only by the low-k film 110 or the insulating film 111. In the embodiment, the first-layer interlayer insulating film 102-1 is formed by the laminated structure made of the low-k film 110 and the insulating film 111.

As shown in FIG. 6, a photoresist is applied onto the insulating film 111 to form a photoresist film 112 having a thickness of 200 nm. Then, the photoresist film 112 is developed after exposed using a photolithography technique. As a consequence, the interconnect patterns 103-1 are made in the photoresist film 112. For example, a laser beam, an electron beam (EB), or an ultraviolet ray (UV) can be used for the exposure.

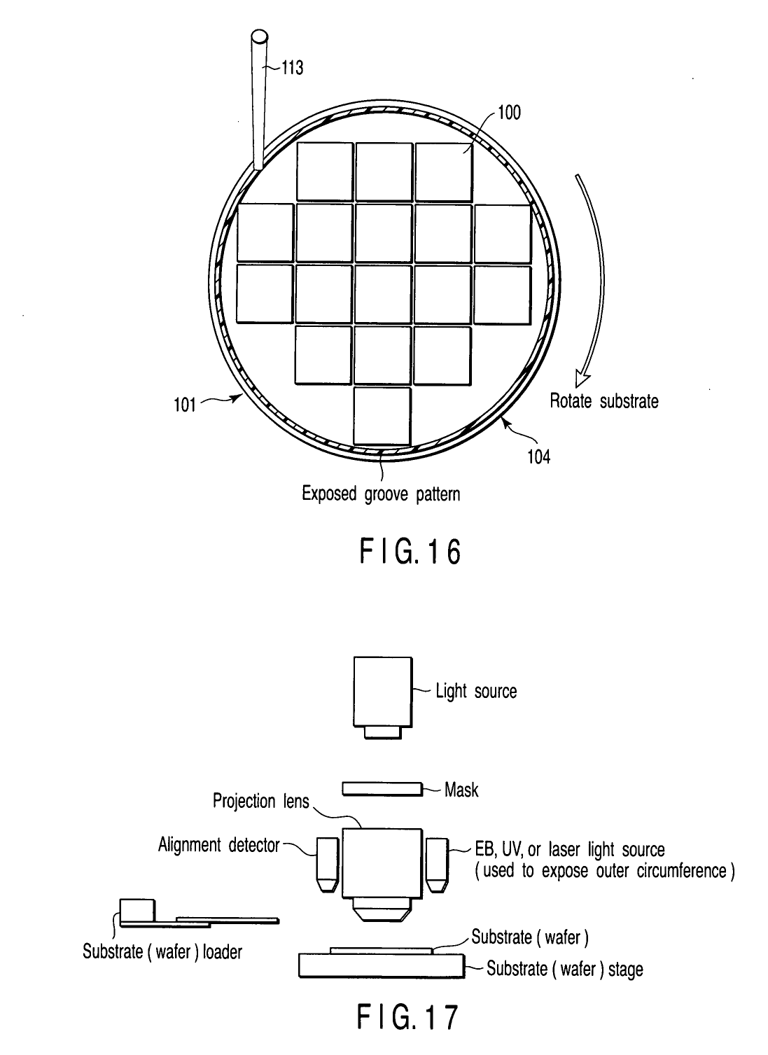

As shown in FIG. 7, after the exposure process of FIG. 6, the semiconductor substrate 101 is rotated about the center of the semiconductor substrate 101 to expose the photoresist film 112 while a region located between the effective chip and the edge 104 of the semiconductor substrate 101 is irradiated with convergent light 113 from above the upper surface of the photoresist film 112. FIG. 16 shows process of FIG. 7 when viewed from above the semiconductor substrate 101. Instead of the convergent light 113, EB and UV may be used in the exposure. FIG. 17 shows an exposure apparatus using in the exposure process of FIG. 7.

As shown in FIG. 17, the exposure apparatus includes a light source, a mask, a projection lens, an alignment detector, a substrate stage, a substrate loader, and an EB, UV, or laser light source. The light source emits light. The light emitted from the light source is incident to the projection lens through the mask, and the light collected by the projection lens is incident to the wafer loaded on the substrate stage, which allows the exposure with the incident light. The alignment detector aligns the mask with the wafer. The substrate loader loads the wafer on the substrate stage. The EB, UV, or laser light source is used as a light source for making a groove pattern if needed.

The groove pattern and the interconnect patterns 103-1 may be exposed at the same time, or the groove pattern may be exposed prior to the exposure of the interconnect patterns 103-1.

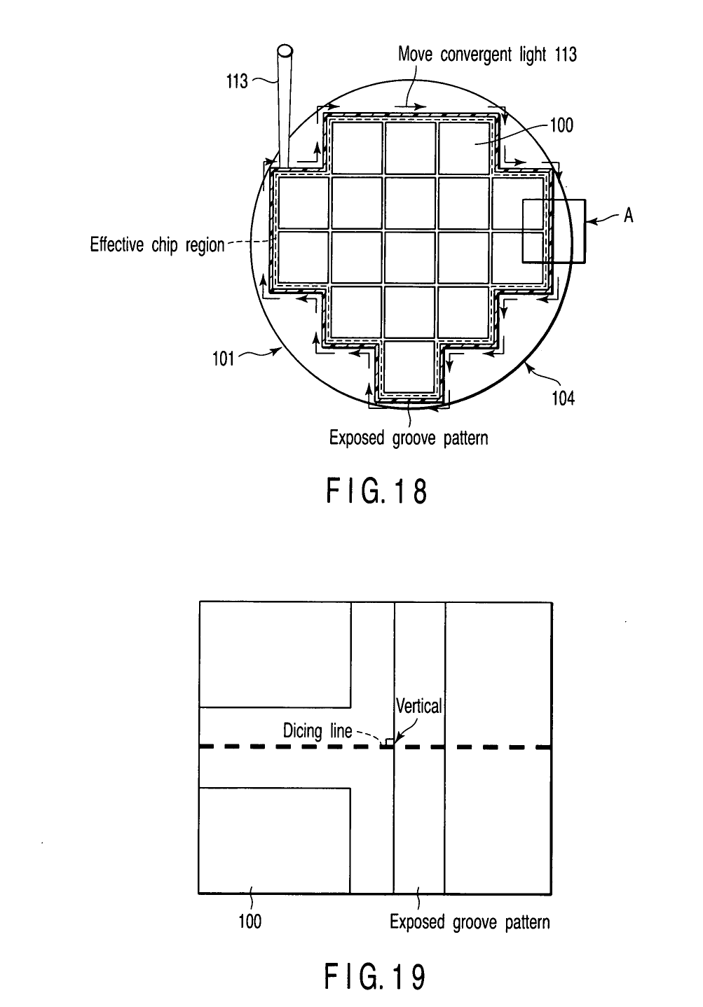

In the circular groove pattern having the concentric relation with the semiconductor substrate 101, there is the advantage that the groove pattern can easily be formed in such a manner that the semiconductor substrate 101 is rotated about the center of the semiconductor substrate 101 while irradiated with the convergent light 113. However, it is not always necessary that the groove pattern be made in the circular shape. For example, as shown in FIG. 18, the groove pattern may be exposed by scanning the convergent light 113 along the outer periphery of the effective chip 100. FIG. 19 is an enlarged view showing a region A of FIG. 18. Referring to FIG. 19, when the groove pattern is made as shown in FIG. 18, generally the orthogonal or parallel relationship is produced between the groove pattern and the dicing line. Therefore, a width of the groove pattern which should be cut in dicing can be minimized. The groove pattern may be exposed by the lithography technique with a reticle in which the groove pattern is drawn in both the circular groove pattern made along the edge 104 and the zigzag groove pattern made along the outer periphery of the effective chip 100.

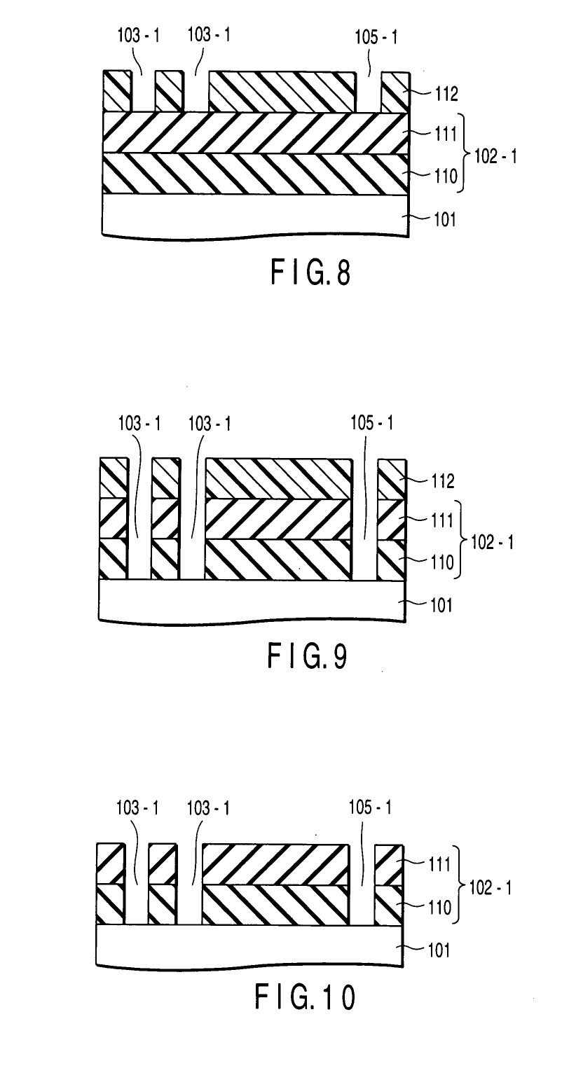

Then, after the exposed photoresist film 112 is stabilized by heat treatment at 180° C., the photoresist film 112 is developed as shown in FIG. 8.

As shown in FIG. 9, the insulating film 111 and the low-k film 110 are etched using the photoresist film 112 as a mask, and the groove pattern 105-1 and the interconnect patterns 103-1 are formed in the insulating film 111 and the low-k film 110. For example, chemical dry etching (CDE) or reactive ion etching (RIE) can be used as the processing method. Basically, a gas containing C, F, O, N, Ar, Cl, Br, H and B is used for the etching, and the etching gas is selected according to a composition of a film to be etched. Examples of the etching gas include a gas containing a CF system or a CO system is selected in the case where the film to be etched has the SiOC system, and a gas containing an O system or an NH₃ system is selected in the case where the film to be etched is made of an organic material. An electric power, a pressure, a gas flow rate and the like are adjusted so as to ensure a selection ratio of the mask material and the film to be etched.

There is no particular limitation to the width of the groove pattern 105-1, and the width can be selected in the wide range of sub-micrometers to thousands micrometers. The effect of the embodiment can be exerted only in one groove pattern 105-1. The larger number of groove patterns 105-1, the better effect of the embodiment can be exerted.

Although as shown in FIGS. 16 and 18, various shapes and arrangements can be adopted for the groove pattern 105-1, the groove pattern 105-1 is made on the edge side of the semiconductor substrate 101 out of the outermost of the effective chip 100. This is because a relative relationship such that the effective chip 100 is placed in the region surrounded by the groove pattern 105-1 is obtained in order to suppress the film peeling of the effective chip 100 with the groove pattern 105-1.

As shown in FIG. 10, ashing and wet etching are performed to peel off the photoresist film 112, and a residue is removed.

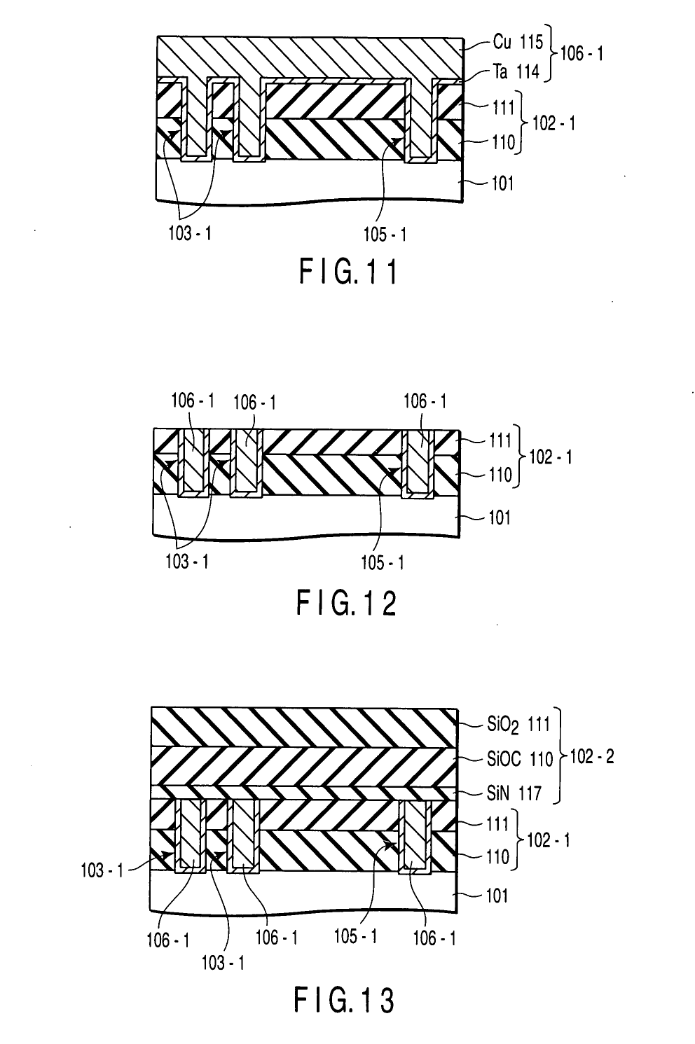

Then, as shown in FIG. 11, a sputtering technique is used to form a barrier metal layer 114 having a thickness of about 20 nm on the interlayer insulating film 102-1. The barrier metal layer 114 is made of a material such as Ta, Ti, a tantalum nitride, and a titanium nitride. In the embodiment, the barrier metal layer 114 is made of Ta. Then, an interconnect-material seed layer having a thickness of about 50 nm is deposited on the barrier metal layer 114. In the embodiment, the seed layer is made of copper. Using an electro plating method, a conductive material 115 is plated on the seed layer, and the interconnect patterns 103-1 and the groove pattern 105-1 are filled with the interconnect material 106-1 having a laminated structure including the barrier metal layer 114 and the conductive material 115. In the embodiment, the conductive material 115 is made of copper. Then, in order to improve reliability of the interconnects, the interconnect material 106-1 is heat treated at 250° C. for one hour.

As shown in FIG. 12, the residual portion of the interconnect material 106-1 is removed by planarization using the CMP method, and damascene interconnects are formed. In the embodiment, damascene interconnects made of copper with the barrier metal layer are formed. At this point, in the groove pattern 105-1, the planarization is performed such that the interconnect material 106-1 is exposed to the upper surface of the interlayer insulating film 102-1.

As shown in FIG. 13, a diffusion blocking film 117 is formed on the interlayer insulating film 102-1 and the interconnect material 106-1. The diffusion blocking film 117 suppresses the diffusion of the element contained in the interconnect material 106-1, particularly the diffusion of copper in the embodiment. In the embodiment, the diffusion blocking film 117 is made of SiN, and the diffusion blocking film 117 has a thickness of 50 nm, for example. Then, the low-k film (for example, SiOC) 110 having a thickness of about 100 nm is formed on the diffusion blocking film 117, and the insulating film (for example, SiO₂) 111 having a thickness of about 100 nm is formed on the low-k film 110. The method of forming the low-k film 110 and the insulating film 111 is similar to the above-described method. In the embodiment, the second-layer interlayer insulating film 102-2 is formed by a laminated structure made of the diffusion blocking film 117, the low-k film 110, and the insulating film 111.

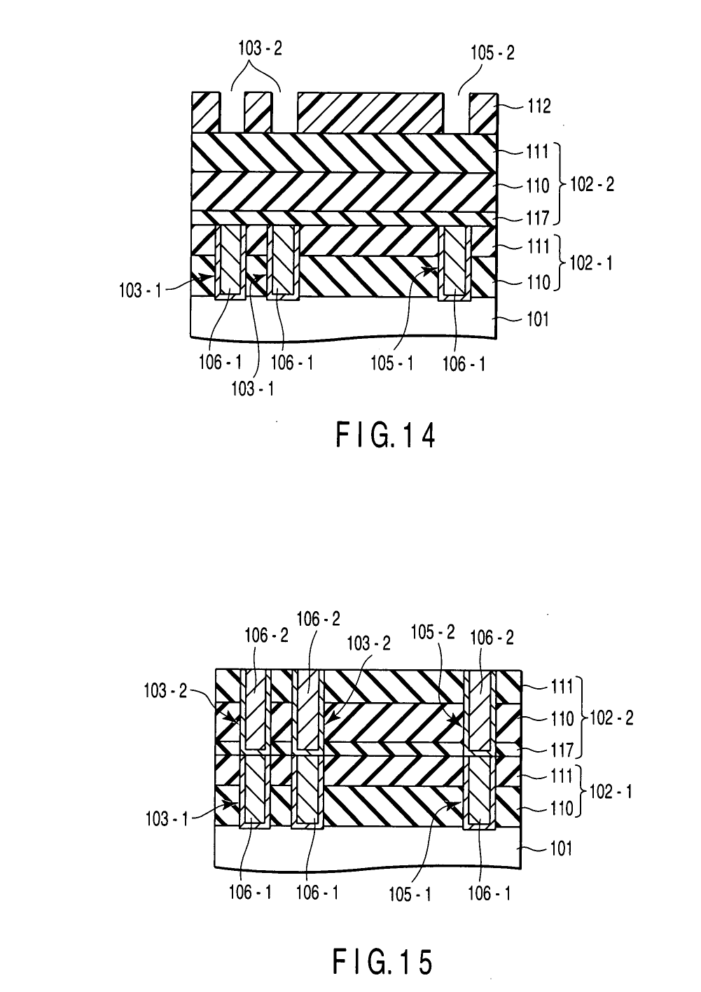

As shown in FIG. 14, the interconnect patterns 103-2 and the groove pattern 105-2 are made in the photoresist film 112 formed on the second-layer interlayer insulating film 102-2 by use of the same methods as those shown in FIGS. 6 to 8.

As shown in FIG. 15, the interconnect patterns 103-2 and groove pattern 105-2 which are made in the second-layer interlayer insulating film 102-2 are filled with the interconnect material 106-2 using the same methods as those shown in FIGS. 9 to 12. At this point, the groove pattern 105-2 is positioned immediately above the groove pattern 105-1, and the etching is performed until the bottom of the groove pattern 105-2 reaches the surface of the interconnect material 106-1 buried in the groove pattern 105-1 during the processing. As a consequence, when the groove pattern 105-2 is filled with the interconnect material 106-2, metal-to-metal contact is achieved between the interconnect material 106-1 and the interconnect material 106-2, which improves the adhesion property.

Predetermined numbers of interlayer insulating films and interconnect materials are formed through the above processes.

Thus, the semiconductor device of the embodiment can be manufactured using the above fabricating method. The embodiment of the invention is not limited to above embodiment, but various modifications can be made without departing from the scope and spirit of the invention.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
an interlayer insulating film formed on a semiconductor substrate including an effective chip;
a first interconnect material formed in an interconnect pattern in the interlayer insulating film, the interconnect pattern being made in a region above the effective chip; and
a second interconnect material formed in a groove pattern in the interlayer insulating film, the groove pattern being made between the region above the effective chip and a region above an edge of the semiconductor substrate, the second interconnect material separating the interlayer insulating film into an inner circumferential portion which includes the region above the effective chip and an outer circumferential portion which does not include the region above the effective chip.

2. The device according to claim 1, wherein the interlayer insulating film includes a first interlayer insulating film and a second interlayer insulating film,
the interconnect pattern includes a first interconnect pattern made in the first interlayer insulating film and a second interconnect pattern made in the second interlayer insulating film,
the groove pattern includes a first groove pattern made in the first interlayer insulating film and a second groove pattern made in the second interlayer insulating film,
the first interconnect material includes a third interconnect material formed in the first interconnect pattern and a fourth interconnect material formed in the second interconnect pattern and connected to the third interconnect material, and
the second interconnect material includes a fifth interconnect material formed in the first groove pattern and a sixth interconnect material formed in the second groove pattern and connected to the fifth interconnect material.

3. The device according to claim 1, wherein the groove pattern is made along the edge of the semiconductor substrate.

4. The device according to claim 1, wherein the groove pattern is made along an outer periphery of the effective chip.

5. The device according to claim 4, wherein the groove pattern is orthogonal or parallel to a dicing line of the semiconductor substrate.

6. The device according to claim 1, wherein the groove pattern is made from a surface of the semiconductor substrate, and the second interconnect material is formed in a fence shape from the surface of the semiconductor substrate to an upper surface of the interlayer insulating film.

7. The device according to claim 1, wherein the interlayer insulating film includes a low-dielectric-constant insulating film whose specific dielectric constant is lower than 3.0.

8. The device according to claim 7, wherein the interlayer insulating film has a laminated structure including a silicon oxide film and the low-dielectric-constant insulating film.

9. The device according to claim 7, wherein the interlayer insulating film has a laminated structure including the low-dielectric-constant insulating film and a diffusion blocking film which suppresses diffusion of a substance contained in the first and second interconnect materials.

10. The device according to claim 7, wherein the interlayer insulating film has a laminated structure including a diffusion blocking film, a silicon oxide film, and the low-dielectric-constant insulating film, the diffusion blocking film suppressing diffusion of a substance contained in the first and second interconnect materials.

11. The device according to claim 7, wherein the low-dielectric-constant insulating film is a film obtained by containing any one of C, H, N, F, Ge, B, P, As, Mn, BF₂, Zn, Sn, Sb, and Hf in the silicon oxide film or an organic polymer film.

12. A method for fabricating a semiconductor device, comprising:
forming an interlayer insulating film on a semiconductor substrate including an effective chip;
making an interconnect pattern in a region above the effective chip in the interlayer insulating film;
making a groove pattern between the region above the effective chip and a region above an edge of the semiconductor substrate in the interlayer insulating film, the groove pattern separating the interlayer insulating film into an inner circumferential portion which includes the region above the effective chip and an outer circumferential portion which does not include the region above the effective chip; and
forming interconnect materials in the groove pattern and the interconnect pattern.

13. The method according to claim 12, wherein the making an interconnect pattern and the making a groove pattern include
forming a photoresist film on the interlayer insulating film;
making a first opening pattern corresponding to the interconnect pattern in a region above the effective chip in the photoresist film;
making a second opening pattern corresponding to the groove pattern between the region above the effective chip and a region above the edge of the semiconductor substrate in the photoresist film; and
removing a part of the interlayer insulating film using, as a mask, the photoresist film having the first opening pattern and the second opening pattern formed thereon, and
the making a second opening pattern includes
rotating the semiconductor substrate about the center of the semiconductor substrate to expose the photoresist film while a region located between the region above the effective chip and the region above the edge of the semiconductor substrate is irradiated with an exposure beam; and
developing the exposed photoresist film.

14. The method according to claim 12, wherein the making an interconnect pattern and the making a groove pattern include
forming a photoresist film on the interlayer insulating film;
making a first opening pattern corresponding to the interconnect pattern in a region above the effective chip in the photoresist film;
making a second opening pattern corresponding to the groove pattern between a region above the effective chip and a region above the edge of the semiconductor substrate in the photoresist film; and
removing a part of the interlayer insulating film using, as a mask, the photoresist film having the first opening pattern and the second opening pattern formed thereon, and
the making a second opening pattern includes
exposing the photoresist film while scanning an exposure beam along an outer periphery of the effective chip; and
developing the exposed photoresist film.

15. The method according to claim 13, wherein the exposure beam includes one of a laser beam, an electron beam, and an ultraviolet ray.

16. The method according to claim 12, wherein the interconnect material is formed using a damascene method.

17. The method according to claim 12, wherein the interlayer insulating film includes a low-dielectric-constant insulating film whose specific dielectric constant is lower than 3.0.

18. The method according to claim 17, wherein the interlayer insulating film has a laminated structure including a silicon oxide film and the low-dielectric-constant insulating film.

19. The method according to claim 17, wherein the interlayer insulating film has a laminated structure including the low-dielectric-constant insulating film and a diffusion blocking film which suppresses diffusion of a substance contained in the first and second interconnect materials.

20. The method according to claim 17, wherein the interlayer insulating film has a laminated structure including a diffusion blocking film, a silicon oxide film, and the low-dielectric-constant insulating film, the diffusion blocking film suppressing diffusion of a substance contained in the first and second interconnect materials.
